(19) United States
(12) Patent Application Publication
(10) Pub. No.: US 2021/0199696 A1
(43) Pub. Date: Jul. 1, 2021

(54) METHOD OF MANUFACTURING PROBE CARD AND PROBE CARD MANUFACTURED USING SAME

(71) Applicant: POINT ENGINEERING CO., LTD., Asan (KR)

(72) Inventors: Bum Mo AHN, Suwon (KR); Seung Ho PARK, Hwaseong (KR); Tae Hwan SONG, Cheonan (KR)

(21) Appl. No.: 17/131,443

(22) Filed: Dec. 22, 2020

(30) Foreign Application Priority Data
Dec. 26, 2019 (KR) 10-2019-0174831

(51) Int. Cl. G01R 3/00; G01R 31/26; G01R 1/073

(52) U.S. Cl. CPC G01R 3/00; G01R 1/07342; G01R 31/2601

(57) ABSTRACT

A method of manufacturing a probe card and a probe card manufactured using the same are disclosed. The method is configured to be capable of collectively attaching probes to a wiring board provided with a connection pad to which the probes are attached.

### CROSS REFERENCE TO RELATED APPLICATION

The present application claims priority to Korean Patent Application No. 10-2019-0174831, filed Dec. 26, 2019, the entire contents of which is incorporated herein for all purposes by this reference.

### BACKGROUND OF THE INVENTION

### Field of the Invention

The present invention relates to a method of manufacturing a probe card, and a probe card manufactured using the same.

### Description of the Related Art

In general, a semiconductor is manufactured through a fabrication process forming a pattern on a wafer, an electrical die sorting (EDS) process inspecting the electrical characteristics of each chip constituting the wafer, and an assembly process assembling the patterned wafer into each individual chip.

Here, the EDS process is performed to determine defective chips among chips constituting the wafer. An inspection device, called a probe card, is mainly used in the EDS process, the probe card being configured so that an electrical signal is applied to the chips constituting the wafer, thereby causing the defective chips to be determined by a signal checked from the applied electrical signal.

The probe card is provided with a probe which contacts a pattern of each chip constituting the wafer to apply an electrical signal. The probe contacts electrode pads of each device on the wafer and measures the electrical characteristics that are output when a specific current is applied.

A patent for such a probe card which is described in Korean Patent No. 10-1823527 (hereinafter, referred to as “Patent Document 1”) is known.

Patent Document 1 may be configured to include a plurality of unit anodic oxide film sheets, anisotropic conductive paste, and probes. In Patent Document 1, a plurality of unit anodic oxide film sheets are stacked and bonded to each other by an anisotropic conductive paste, and the probes may be electrically connected by a conductor provided inside the unit anodic oxide film sheet.

The anodic oxide film material is effective in preventing thermal deformation, since the anodic oxide film material is easy to implement a narrow pitch of the through hole in which the via conductor is equipped and has a low coefficient of thermal expansion.

There is a need to develop a technology for efficiently attaching a probe to a wiring board made of such an anodic oxide film.

### Documents of Related Art

[Patent Document 1] Korean Patent No. 10-1823527

### SUMMARY OF THE INVENTION

The present invention has been conceived to solve the above-mentioned problems, and it is an objective of the present invention to provide a method of manufacturing a probe card, the method configured to be capable of collectively attaching probes to a wiring board provided with a connection pad to which the probes are attached, thereby bonding the probes while improving production speed and minimizing damage to the surface of the wiring board.

In addition, it is an objective of the present invention is to provide a probe card in which a probe is efficiently attached to a multilayer wiring board configured to include an anodic oxide wiring board made of an anodic oxide film material.

According to an aspect of the present invention, a method of manufacturing a probe card includes forming a temporary layer on a surface of a base substrate, forming a masking material layer on a surface of the temporary layer and patterning the masking material layer to form an open area, filling the open area with a conductive material, and removing the masking material layer excluding the conductive material by an etching process; manufacturing a multilayer wiring board configured to have an anodic oxide film wiring board which is provided with a plurality of vertical wiring portions and horizontal wiring portions inside and made of an anodic oxide film material; placing the base substrate, to which the conductive material is attached, above a probe connection pad of the multilayer wiring board to bond one end of the conductive material to the probe connection pad; and removing the temporary layer of the base substrate through an etching process using an etchant to separate the other end of the conductive material from the base substrate.

In addition, a surface of the multilayer wiring board may be composed of a barrier layer.

In addition, the manufacturing of the multilayer wiring board may include bonding a sintered ceramic wiring board to the top or bottom of the anodic oxide film wiring board.

In addition, the manufacturing of the multilayer wiring board may include bonding a resin insulating layer wiring board composed of a resin insulating layer to the top or bottom of the anodic oxide film wiring board.

According to another aspect of the present invention, a probe card includes a multilayer wiring board in which a vertical wiring portion and a horizontal wiring portion are provided and on which a probe connection pad is provided; and a probe having one end connected to the probe connection pad, wherein the multilayer wiring board is configured to include an anodic oxide film wiring board made of an anodic oxide film material, so that a surface of the multilayer wiring board is composed of a barrier layer, and the probe connection pad is provided on a surface of the barrier layer.

In addition, the multilayer wiring board may include a sintered ceramic wiring board made of a sintered ceramic material provided on the bottom of the anodic oxide film wiring board and.

In addition, the multilayer wiring board may include a resin insulating layer wiring board composed of a resin insulating layer provided on the bottom of the anodic oxide film wiring board.

According to another aspect of the present invention, a probe card includes a multilayer wiring board in which a vertical wiring portion and a horizontal wiring portion are provided and on which a probe connection pad is provided; and a probe connected to the probe connection pad, wherein the multilayer wiring board includes an anodic oxide film wiring board made of an anodic oxide film material and a sintered ceramic wiring board made of a sintered ceramic material provided on the top of the anodic oxide film wiring board, and the probe connection pad is provided on a surface of the sintered ceramic wiring board.

According to another aspect of the present invention, a probe card includes a multilayer wiring board in which a vertical wiring portion and a horizontal wiring portion are provided and on which a probe connection pad is provided; and a probe connected to the probe connection pad, wherein the multilayer wiring board is configured to include an anodic oxide film wiring board made of an anodic oxide film material and a resin insulating layer wiring board made of a resin insulating layer provided on the top of the anodic oxide film wiring board, and the probe connection pad is provided on a surface of the resin insulating layer wiring board.

According to the present invention, a probe can be collectively bonded to a probe connection pad, thereby performing a rapid process. In addition, the surface of the multilayer wiring board is configured to have corrosion resistance to the etchant used to collectively separate the probe from the substrate to which one end of the probe is attached, so that the probe bonding process can be performed without damaging the surface thereof. This allows the process to be efficiently performed without damaging the probe card, whereby there is an effect of improving the production speed of the probe card.

### BRIEF DESCRIPTION OF THE DRAWINGS

The above and other objectives, features, and other advantages of the present invention will be more clearly understood from the following detailed description when taken in conjunction with the accompanying drawings, in which:

FIG. 1 is a view schematically showing a probe card according to a first embodiment of the present invention;

FIGS. 2A-2D and 3A-3B are views schematically showing a process of manufacturing a probe provided in a probe card according to the present invention;

FIGS. 4A-4B and 5A-5B are views schematically showing the bonding process of a probe in an enlarged manner.

FIG. 6 is a view schematically showing a probe card according to a second embodiment of the present invention; and

FIG. 7A-7D is a view schematically showing embodiments of various structures of a multilayer wiring board constituting a probe card of the present invention.

### DETAILED DESCRIPTION OF THE INVENTION

The following merely illustrates the principles of the invention. Therefore, those skilled in the art can implement the principles of the invention and invent various devices included in the concept and scope of the invention, although not explicitly described or illustrated herein. In addition, all conditional terms and embodiments listed herein are in principle clearly intended for the purpose of understanding the concept of the invention and should be understood not to be limited to the specifically listed embodiments and states.

The above objectives, features, and advantages will become more apparent from the following detailed description taken in conjunction with the accompanying drawings, whereby the technical spirit of the invention may be easily implemented by those skilled in the art.

Embodiments described in the present specification will be described with reference to sectional views and/or perspective views that are ideal examples of the present invention. The thickness and width of members and regions shown in these drawings are exaggerated for effective description of technical content. The shape of the illustrative diagram may be modified by manufacturing techniques and/or tolerances.

In addition, the number of holes illustrated in the drawings is only partially illustrated in the drawings by way of example. Accordingly, embodiments of the present invention are not limited to the specific form shown, but also include a change in form generated according to a manufacturing process.

In describing various embodiments, elements that perform the same function will be given the same name and the same reference number for convenience even though the embodiments are different. In addition, the configuration and operation already described in the other embodiments will be omitted for convenience.

Hereinafter, preferred embodiments of the present invention will be described in detail with reference to the accompanying drawings.

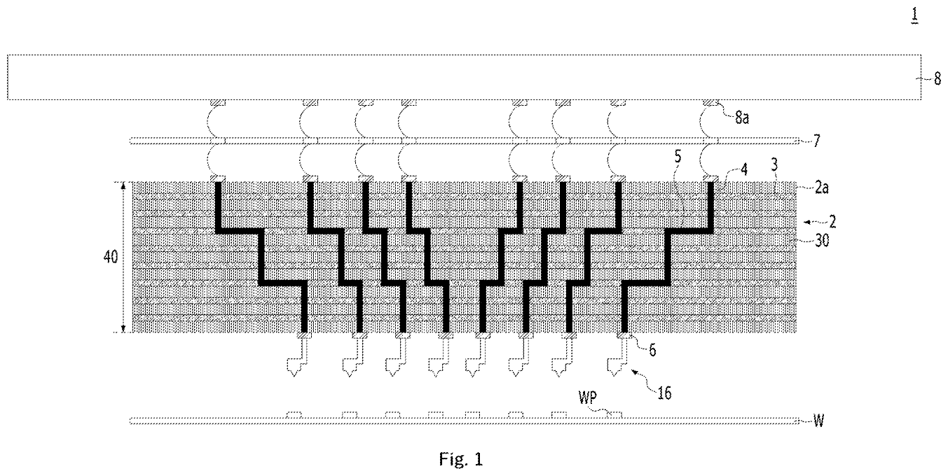

FIG. 1 is a view schematically showing a probe card 1 according to a first embodiment of the present invention. In FIG. 1, the number and size of a plurality of probes 16 are shown exaggeratedly for convenience of description.

The probe card 1 may be divided into a vertical type probe card, a cantilever type probe card, and a MEMS probe card 1 according to the structure of the probe 16 and the structure in which the probes 16 are installed on the multilayer wiring board 2. According to the present invention, for example, the MEMS probe card 1 is shown, and herein the probe card 1 may include the probe 16 manufactured by using a method of manufacturing a probe card (hereinafter, referred to as “probe card manufacturing method”) according to the present invention. In other words, the probe card 1 illustrated in FIG. 1 may be a probe card provided with the probe 16 by using the probe card manufacturing method according to the present invention.

As shown in FIG. 1, the probe card 1 of the present invention is made of an anodic oxide film 30 and is configured to include a multilayer wiring board 2 in which a vertical wiring portion 4 and a horizontal wiring portion 5 are provided and on which a probe connection pad 6 is provided, a circuit board 8 provided above the multilayer wiring board 2, an interposer 7 that electrically connects the circuit board 8 with the multilayer wiring board 2 between the circuit board 8 and the multilayer wiring board 2, and a plurality of probes 16.

The probe card 1 having such a configuration may perform an electrical characteristic test by causing the plurality of probes 16 to be in contact with the corresponding electrode pads WP on the semiconductor wafer W.

As shown in FIG. 1, the multilayer wiring board 2 may be configured so that a plurality of unit anodic oxide film wiring boards 2a made of a material of an anodic oxide film 30 are stacked. The unit anodic oxide film wiring board 2a may be configured in such a manner as to be bonded to each other by the bonding layer 3.

The bonding layer 3 may be a photosensitive material, for example, a dry film photoresist (DFR). Meanwhile, the bonding layer 3 may be a thermosetting resin. The thermosetting resin material may be a polyimide resin, a polyquinoline resin, a polyamideimide resin, an epoxy resin, a polyphenylene ether resin, and a fluororesin.

The bonding layer 3 may be provided between the unit anodic oxide film wiring boards 2a and thus patterned. A horizontal wiring portion 5 may be provided in the patterned area. Accordingly, the bonding layer 3 may serve to provide a space in which the horizontal wiring portion 5 provided on the surface of the unit anodic oxide film wiring board 2a may be formed. In addition, the bonding layer 3 serves to bond the unit anodic oxide film wiring boards 2a to each other by areas that are not removed and not patterned after providing the horizontal wiring portion 5 in the patterned area.

Accordingly, the bonding layer 3 may simultaneously perform a bonding function and a space providing function for forming the horizontal wiring portion 5. Accordingly, the bonding layer 3 is configured to have photosensitive properties since it should be patterned by a photoresist process and retain properties as a bonding material since it should perform the bonding function.

The bonding layer 3 for bonding the unit anodic oxide film wiring boards 2a may be provided on at least one side of the anodic oxide film 30 according to a structure in which the unit anodic oxide film wiring boards 2a are stacked. According to the present invention, as an example, the bonding layer 3 may be provided at the upper portion of the anodic oxide film 30.

The anodic oxide film 30 refers to a film formed by anodizing a metal of base material, and a pore hole 30a refers to a hole formed in the process of forming the anodic oxide film 30 by anodizing the metal. For example, in the case that the metal of base material is aluminum (Al) or an aluminum alloy, when the base material is anodized, the anodic oxide film 30 made of anodized aluminum (Al₂O₃) material is formed on the surface of the base material. The anodic oxide film 30 formed as described above is divided into a barrier layer BL having no pore holes 30a formed therein, and a porous layer PL having pore holes 30a formed therein. The barrier layer BL is positioned at the upper portion of the base material, and the porous layer PL is positioned at the upper portion of the barrier layer BL. When the barrier layer BL is removed from the base material on which the anodic oxide film 30 having the barrier layer BL and the porous layer PL is formed, only the anodic oxide film 30 made of anodized aluminum (Al₂O₃) material remains. The anodic oxide film 30 has pore holes 30a having a uniform diameter and arranged a regularly while being formed in a vertical shape. Herein, when the barrier layer BL are removed, a structure in which the pore holes 30a vertically penetrate is provided.

In the case of a material of the anodic oxide film 30, it has a coefficient of thermal expansion of 2 to 3 ppm/° C. Therefore, there is an advantage that there is little deformation due to temperature. Since the probe card 1 of the present invention has a multilayer wiring board 2 made of a material of the anodic oxide film 30, it is more preferable in performing a process in a high temperature environment.

In addition, the multilayer wiring board 2 having a structure in which a plurality of unit anodic oxide film wiring boards 2a are stacked may have improved durability. As a result, the probe card 1 according to the present invention can show an effect of being advantageous and durable in a high temperature environment.

The probe 16 provided on the surface of the multilayer wiring board 2 may be manufactured on a separate substrate (for example, the base substrate 10), and then bonded to the probe connection pad 6 of the multilayer wiring board 2.

The probe card manufacturing method according to the present invention is configured to include a step of forming a temporary layer 11 on the surface of the base substrate 10, forming a masking material layer MKL on the surface of the temporary layer 11 and patterning the same to form an open area OF, filling the open area OF with conductive material C, and removing the masking material layer MKL excluding the conductive material C by an etching process; a step of manufacturing a multilayer wiring board 2 configured to have an anodic oxide film wiring board 40 which is provided with a plurality of vertical wiring portions and horizontal wiring portions 4 and 5 inside and made of a material of the anodic oxide film 30; a step of placing the base substrate 10, to which the conductive material C is attached, above the probe connection pad 6 of the multilayer wiring board 2 made of a material of the anodic oxide film 30 to bond one end of the conductive material C to the probe connection pad 6; and a step of removing the temporary layer 11 of the base substrate 10 through an etching process using an etchant to separate the other end of the conductive material C from the base substrate 10, Herein, the surface of the multilayer wiring board 2 may have corrosion resistance to the etchant.

The probe card 1 in the present invention may include the probe 16 manufactured by using the probe bonding process of the probe card manufacturing method in the present invention as described above. Accordingly, the surface of the multilayer wiring board 2 constituting the probe card 1 according to the present invention may be configured with a material having corrosion resistance to an etchant.

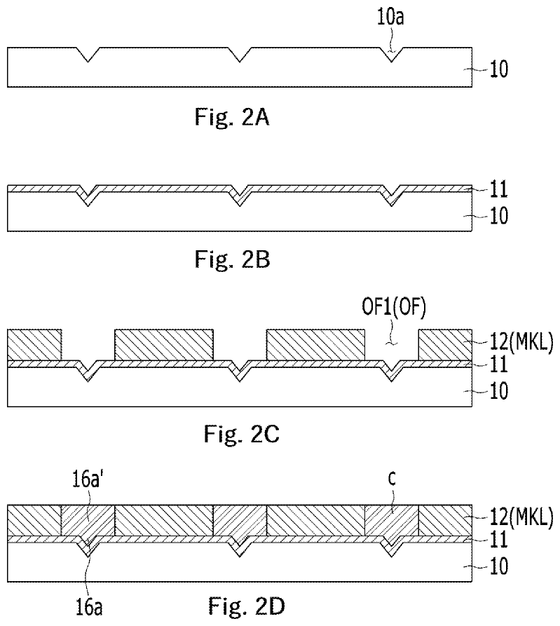

First, the probe card manufacturing method according to the present invention will be described in detail with reference to FIGS. 2 to 5. FIGS. 2 to 5 illustrate a shape of the probe 16, for example. Therefore, the shape of the probe 16 formed according to a step of forming the probe 16 of the present invention is not limited to the shape shown in FIGS. 2 to 5.

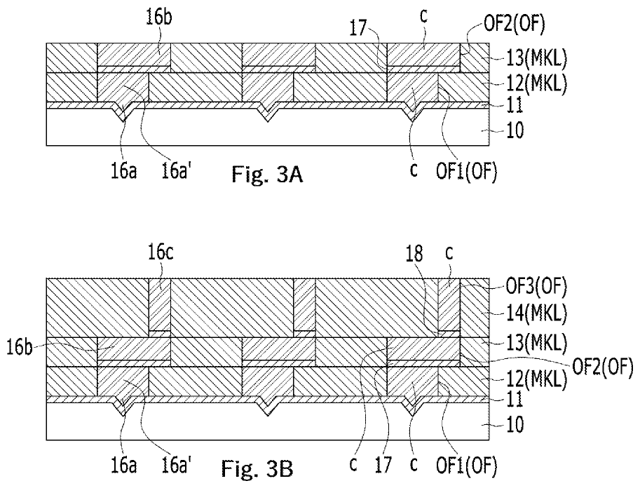

FIGS. 2 and 3 are views schematically showing steps of forming a plurality of probes 16 on a base substrate 10.

As shown in (a) of FIG. 2, the base substrate 10 may be provided. The base substrate 10 may be a substrate temporarily supporting the probes 16 formed by filling the conductive material C in the open area OF. The base substrate 10 may be, but is not limited to, a silicon wafer, a ceramic substrate, a printed circuit board, a metal substrate, a substrate including an organic material or an inorganic material, a metal substrate, a plastic substrate, and the like. In the present invention, for example, the base substrate 10 may be composed of a silicon wafer.

A groove 10a may be formed in the base substrate 10 to configure a tip portion 16a of the probe 16. The groove 10a may be formed by an etching process, for example. As another example, it may be formed using a lithographic technique.

When the groove 10a is formed using a lithographic technology, for example, the base substrate 10 may be a silicon wafer. First, an oxide layer may be formed on the wafer, and then patterned after forming a masking material layer. A part of the oxide layer may be exposed by patterning. The exposed portion of the oxide layer may be etched using an etchant such as hydrogen fluoride. This may make it possible to expose a portion of the wafer. Then, a step of removing the masking material and then etching a part of the exposed wafer may be performed. In the etching of the part of the exposed wafer, a shape formed through etching may be formed in the shape of the groove 10a.

The shape of the groove 10a may be formed in, for example, a triangular cross-sectional shape having an opening. The shape of the groove 10a is not limited thereto, but may be appropriately formed according to the shape of the tip portion 16a of the probe 16. As another example of the shape of the tip portion 16a, a pyramid, a truncated pyramid, a blade, and a bump may be included. The groove 10a may be formed via any suitable method including an etching process, stamping, carving, laser cutting, erosion, and the like.

Then, as shown (b) of FIG. 2, a temporary layer 11 may be formed on the surface of the base substrate 10. Since the temporary layer 11 is formed on the surface of the base substrate 10, the temporary layer 11 may function to facilitate separation of the base substrate 10 and the probe 16 when the probe 16 is formed on the base substrate 10.

The temporary layer 11 may be electrically conductive, and may function as an anode or a cathode in an electroplating process in which the conductive material C for forming the probe 16 is electrically plated onto the temporary layer 11. The temporary layer 11 may be composed of aluminum, copper, gold, titanium, tungsten, silver, and alloys thereof. Preferably, the temporary layer 11 in the present invention may be made of a copper (Cu) material.

The temporary layer 11 may be deposited by any suitable method, including chemical vapor deposition, physical vapor deposition, sputter deposition, electroless plating, electron beam deposition, and thermal evaporation.

Then, as shown in (c) of FIG. 2, a masking material layer MKL may be formed on the surface of the temporary layer 11. The masking material layer MKL may be patterned by a photoresist process to form an open area OF. Therefore, it may be made of a material having photosensitive properties. In other words, the masking material layer MKL may be made of a photosensitive material, for example, a photosensitive film (DFR). The masking material layer MKL formed on the surface of the temporary layer 11 may be the first masking material layer 12. Accordingly, the open area OF formed by patterning the first masking material layer 12 may be a first open area OF1.

The first open area OF1 formed by patterning the first masking material layer 12 may be formed at a position corresponding to the groove 10a. In other words, the first open area OF1 may be formed by patterning the first masking material layer 12 at a position corresponding to the groove 10a.

Then, as shown in (d) of FIG. 2, a process of filling the conductive material C in the first open area OF1 may be performed. The conductive material C filled in the first open area OF1 may constitute the other end 16a′ including the tip portion 16a of the probe 16.

After the conductive material C is filled in the first open area OF1 of the first masking material layer 12, a process of flattening the exposed surface of the conductive material C filled in the first open area OF1 and the exposed surface of the first masking material layer 12 is performed.

Then, as shown in (a) of FIG. 3, a process of forming the second masking material layer 13 on the first masking material layer 12 may be performed. A patterning process may be performed on the second masking material layer 13 at a position corresponding to the first open area OF1 of the first masking material layer 12. As a result, a second open area OF2 may be formed. A first plating layer 17 may be formed at the lower part of the second open area OF2 through electroplating. The first plating layer 17 may function as an anode or a cathode. Then, a process of filling the second open area OF2 with the conductive material C may be performed. The conductive material C filled in the first open area OF1 and the conductive material C filled in the second open area OF2 may be electrically connected by the first plating layer 17 formed between the open areas OF1 and OF2. An intermediate portion 16b of the probe 16 may be formed by filling the conductive material C in the second open area OF2 of the second masking material layer 13. As a method of filling the conductive material C in the first and second open areas OF1 and OF2, suitable methods may be used including, but is not limited thereto, electroplating, chemical vapor deposition, physical vapor deposition, sputter deposition, electroless plating, electron beam deposition, and thermal deposition.

In FIG. 3 of the present invention, as an example, although it is shown that the second open area OF2 is formed to have a width larger than the width of the first open area OF1 at a position corresponding to the first open area OF1, the shape of the open area OF is not limited thereto.

Then, a process of flattening the exposed surface of the conductive material C filled in the second open area OF2 and the exposed surface of the second masking material layer may be performed.

Then, as shown in (b) of FIG. 3, a process of forming the third masking material layer 14 on the second masking material layer 13 may be performed. A third open area OF3 may be formed on the third masking material layer 14 through patterning. The third open area OF3 is formed to have a width smaller than the width of the second open area OF2 at a position corresponding to the second open area OF2.

A second plating layer 18 may be formed in the lower part of the third open area OF3. The second plating layer 18 is formed by electroplating to function as an anode or a cathode.

Then, the conductive material C may be filled in the third open area OF3. The conductive material C filled in the third open area OF3 may constitute one end 16c of the probe 16.

Then, a process of flattening the exposed surface of the third masking material layer 14 and the exposed surface of the conductive material C filled in the third open area OF3 may be performed.

Then, a process of removing the masking material layer MKL excluding the conductive material C on the base substrate 10 through an etching process may be performed. Through this process, a shape in which the probe 16 made of the conductive material C filled in each of the open areas OF1, OF2, and OF3 is attached to the temporary layer 11 on the base substrate 10 may be implemented.

In the present invention, it has been described that masking material layers (MKLs) are repeatedly provided on the base substrate 10 having the temporary layer 11 provided thereon to form the probe 16, with reference to FIGS. 2 and 3. The process of forming the probe 16 on the base substrate 10 having the temporary layer 11 provided thereon is not limited thereto, and some other processes may be added to the process, or the probe 16 may be formed according to other processes. As another example, after the first masking material layer 12 is provided on the base substrate 10 in which the groove 10a is formed and on which the temporary layer 11 is provided, the first open area OF1 may be formed by performing patterning at a location corresponding to the location where the groove 10a is formed. Then, a material constituting the tip portion 16a of the probe 16 may be deposited on a part of the temporary layer 11 exposed by the first open area OF1 by electroplating or other suitable methods (for example, chemical vapor deposition, physical vapor deposition, sputter deposition, electroless plating, electron beam deposition, and thermal deposition). Herein, the material constituting the tip portion 16a may be palladium, gold, rhodium, nickel, cobalt, silver, platinum, conductive nitride, conductive carbide, tungsten, titanium, molybdenum, rhenium, indium, osmium, rhodium, copper, refractory metal, alloys thereof, and a suitable material including a combination thereof, but is not limited thereto.

In the probe 16 having the other end 16a including the tip portion 16a attached to the base substrate 10 by the temporary layer 11, a process of bonding one end 16c of the probe 16 to the probe connection pad 6 provided in the multilayer wiring board 2 may be performed.

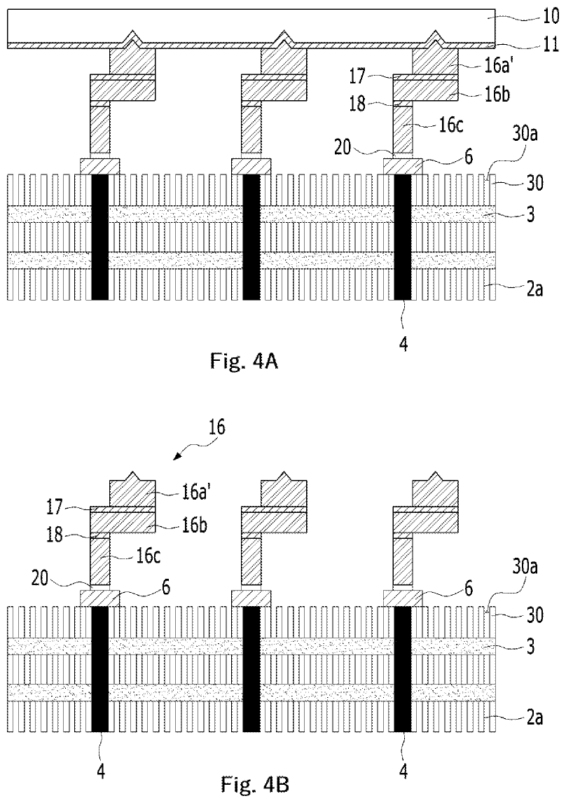

A view (a) of FIG. 4 is an enlarged view showing a process of bonding one end of the probe 16 having the other end 16a′ attached to the base substrate 10 to the probe connection pad 6.

As shown in (a) of FIG. 4, a process of inverting the base substrate 10, to which the other end 16a′ of the probe 16 of a conductive material C is attached, and then placing the same above the probe connection pad 6 of the multilayer wiring board 2 may be performed. One end 16c of the probe 16, which is not attached to the base substrate 10, may be bonded to the probe connection pad 6 by, for example, a solder layer 20 provided on the probe connection pad 6. Alternatively, the bonding may be performed by eutectic bonding, in addition to the solder layer 20. Herein, the bonding may be performed using a eutectic bonding layer that is made of a combination of Ni/Sn, Ag/Sn/Cu, Ag/Sn, Cu/Sn, Au/Sn, or the like.

Then, a process of removing the temporary layer 11 of the base substrate 10 may be performed by an etching process using an etchant. According to the present invention, the temporary layer 11 may preferably be made of a Cu material. Therefore, a Cu etchant may be used as an etchant for removing the temporary layer 11. As shown in (b) of FIG. 4, the temporary layer 11 may be separated from the base substrate 10 at the other end 16a′ of the probe 16 through the process of removing the temporary layer 11 by the etching process.

The probe card 1 in the present invention may be provided with a multilayer wiring board 2 made of a material of the anodic oxide film 30. The multilayer wiring board 2 made of a material of the anodic oxide film 30 may have corrosion resistance to Cu etchant. Therefore, as shown in (b) of FIG. 4, even when the temporary layer 11 is removed using a Cu etchant to separate the other end 16a′ of the probe 16 from the base substrate 10, it is possible to prevent a problem that the surface of the multilayer wiring board 2 is etched.

In other words, the probe card 1 in the present invention may be configured so that the surface of the multilayer wiring board 2 has corrosion resistance to the etchant. Therefore, after a plurality of probes 16 is manufactured at once on the base substrate 10 by using the method of manufacturing the probe card of the present invention without damage to the surface by the etchant, a process of locating the base substrate 10 provided with the probe 16 above the probe connection pad 6 to collectively bond one end of the probe 16 to the probe connection pad 6 and collectively attaching a plurality of probes 16 to the probe connection pad 6 by separating the base substrate 10 from the other end 16a′ of the probe 16 through an etching process may be effectively performed.

As a result, a process of rapidly bonding the probe 16 may be performed. As a result, since the probe 16 is separately manufactured so that the probe 16 is bonded to the probe connection pad 6, the production speed of the produced probe card 1 may be increased.

As shown in FIGS. 1 and 4, according to the first embodiment, the multilayer wiring board 2 constituting the probe card 1 is configured with an anodic oxide film 30 with the barrier layer BL being removed, so that a surface of the multilayer siring board is composed of a porous layer PL including pore holes 30a. In this case, the temporary layer 11 of the base substrate 10 may be preferably made of a Cu material. Then, in the process of separating the other end 16a′ of the probe 16 from the base substrate 10 above the upper side of the multilayer wiring board 2, a Cu etchant may be used. The multilayer wiring board 2, which is made of a material of the anodic oxide film 30 to have a surface composed of a porous layer (PL), has corrosion resistance to the Cu etchant, thereby preventing the problem that the surface is etched during the probe bonding process.

Alternatively, the multilayer wiring board 2 may be composed of an anodic oxide film 30 including a barrier layer BL and a porous layer PL. Herein, in the multilayer wiring board 2 provided so that a plurality of unit anodic oxide film wiring boards 2a are stacked, the surface of the side in which the probe 16 is provided is composed of a barrier layer BL. Thus, the surface of the multilayer wiring board 2 of the side in which the probe connection pad 6 is provided may be composed of a barrier layer BL. In other words, the probe connection pad 6 may be provided on the surface of the barrier layer BL.

The unit anodic oxide film wiring board 2a in the remaining layer, excluding the unit anodic oxide film wiring board 2a provided with the probe connection pad 6 may be configured to include a barrier layer BL and/or a porous layer PL. However, when both the upper and lower surfaces of the multilayer wiring board 2 are symmetrically configured with the barrier layer BL, the density of the surface of the multilayer wiring board 2 becomes uniform, whereby it is more advantageous in terms of bending deformation prevention in a high temperature environment. Therefore, preferably, the upper and lower surfaces of the multilayer wiring board 2 may be configured symmetrically with the barrier layer BL and provided with a unit anodic oxide film wiring board 2a.

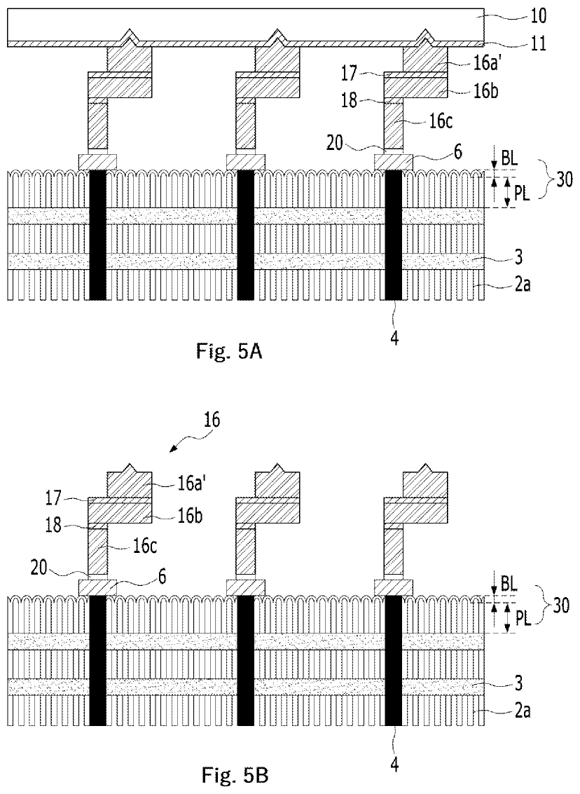

FIG. 5 is an enlarged view schematically showing a process of bonding the probe by performing the probe card manufacturing method according to the present invention for a multilayer wiring board 2 in which the surface having the probe connection pad 6 is configured with a barrier layer BL.

As shown in (a) of FIG. 5, a process of placing the base substrate 10, to which the other end of the probe 16 of a conductive material C is attached, above the probe connection pad 6 of the multilayer wiring board 2 made of a material of the anodic oxide film 30 may be performed. Then, one end of the probe 16 attached to the base substrate 10 may be bonded by a solder layer 20 provided on the probe connection pad 6.

Then, as shown in (b) of FIG. 5, the temporary layer 11 of the base substrate 10 is removed using an etchant, so that a process of separating the other ends 16a′ of the plurality of probes 16 from the base substrate 10 may be performed. Accordingly, a process of collectively bonding the plurality of probes 16 to the probe connection pad 6 of the multilayer wiring board 2 may be performed.

The probe connection pad 6 to which the probe 16 is bonded may be provided on the surface of the multilayer wiring board 2 composed of the barrier layer BL. In the case of the barrier layer BL, a relatively larger amount of aluminum (Al) may be included than in the porous layer PL including the pore holes 30a. In addition, the barrier layer BL is a layer in which the pore holes 30a do not exist and may have a higher density than the porous layer PL. Accordingly, the barrier layer BL may be more advantageous than the porous layer PL in terms of chemical corrosion resistance.

Therefore, even when a process of separating the other ends 16a′ of the plurality of probes 16 from the base substrate 10 above the probe connection pad 6 using an etchant is performed, there is no problem that the surface of the multilayer wiring board 2 is damaged due to the etchant.

When the multilayer wiring board 2 is composed of a barrier layer BL, the temporary layer 11 of the base substrate 10 may be made of a material including aluminum, copper, gold, titanium, tungsten, silver, and alloys thereof, as described above with reference to FIG. 2. The etchant used to remove the temporary layer 11 from the base substrate 10 may be suitably selected as an etchant according to the material constituting the temporary layer 11.

As shown in FIG. 5, when the surface of the multilayer wiring board 2 is composed of the barrier layer BL, since the surface of the multilayer wiring board 2 has a higher density compared to when the surface is composed of the porous layer PL, the chemical corrosion resistance may be relatively strong. Therefore, even when the temporary layer 11 is composed of at least one of the other components of the temporary layer 11 including copper (Cu) material, the problem that the surface is damaged due to the etchant for removing the temporary layer 11 may be minimized.

As described, since the probe card is configured to include a multilayer wiring board 2 which is composed of anodic oxide film material, the multilayer wiring board 2 having the vertical wiring portion 4 and the horizontal wiring portion 5 provided therein and the probe connection pad 6 provided thereon, a solder layer 20 provided on the surface of the probe connection pad 6, and a probe 16 having one end connected to the probe connection pad 6 by the solder layer 20 and is configured so that the surface of the multilayer wiring board 2 is composed of the barrier layer BL, the probe card has a high surface density, so that the corrosion resistance to the etchant may be strong.

Accordingly, when bonding the probe 16 according to the probe card manufacturing method of the present invention, a process of collectively bonding the probes 16 to the probe connection pad 6 and removing the base substrate 10 may be performed without damage to the surface due to the etchant. As a result, the probe bonding process required to manufacture the probe card 1 may be quickly performed. In addition, since there is no problem that the probe card 1 is damaged during the probe bonding process, it is possible to efficiently manufacture the probe card having a high durability.

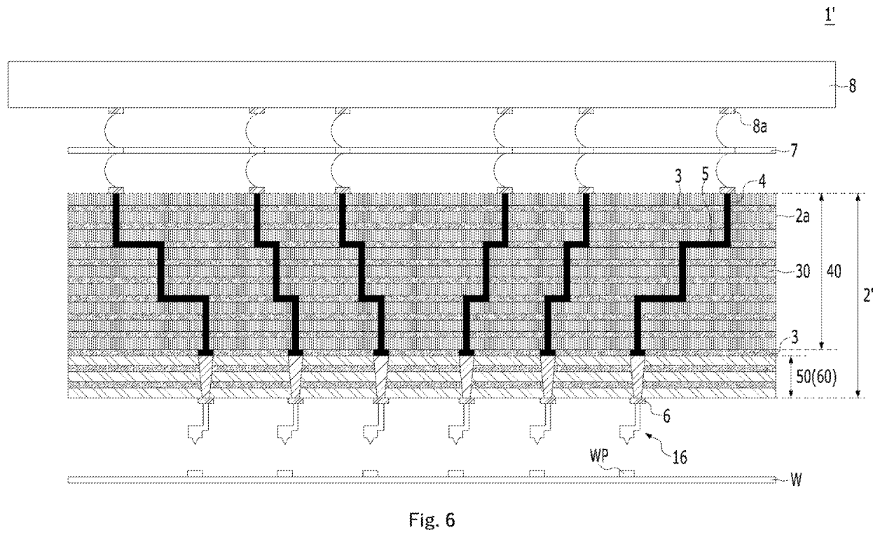

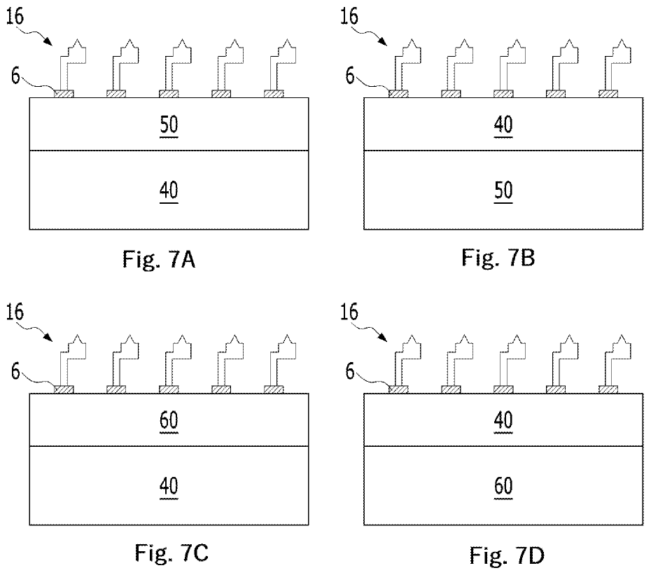

FIG. 6 is a view schematically showing a probe card 1′ according to a second embodiment of the present invention, and FIG. 7 is a view schematically showing embodiments of various structures of multilayer wiring boards 2 and 2′ constituting the probe cards 1 and 1′ of the present invention. The probe card 1′ according to the second embodiment may include a probe 16 manufactured by using the probe card manufacturing method according to the present invention. The probe card 1′ of the second embodiment differs from the probe card 1 of the first embodiment in that it is configured with an anodic oxide film wiring board 40 in which the multilayer wiring board 2′ is composed of a material of the anodic oxide film 30, and a sintered ceramic wiring board 50 provided on the top or bottom of the anodic oxide film wiring board 40 and made of a sintered ceramic material. Since other configurations and structures except for this are the same as those of the probe card 1 of the first embodiment, characteristic configurations and structures will be mainly described with respect to the second embodiment.

The multilayer wiring board 2′ is configured to include an anodic oxide film wiring board 40 made of a material of the anodic oxide film 30 and the sintered ceramic wiring board 50 provided on the top or bottom of the anodic oxide film wiring board 40 and made of a sintered ceramic material so that its surface may be made of a sintered ceramic material.

The anodic oxide film wiring board 40 may be provided so that a plurality of unit anodic oxide film wiring boards 2a are bonded to the bonding layer 3.

The sintered ceramic wiring board 50 may be a wiring board obtained by sintering a ceramic green sheet including alumina powder or mullite powder at high temperature.

The anodic oxide film wiring board 40 and the sintered ceramic wiring board 50 constituting the multilayer wiring board 2′ may be separately manufactured and bonded to each other by a bonding layer 3. Herein, the bonding layer 3 may have the same configuration as the bonding layer 3 bonding the unit anodic oxide film wiring boards 2a to each other. However, the bonding method of the anodic oxide film wiring board 40 and the sintered ceramic wiring board 50 is not limited thereto, and known methods of bonding wiring boards made of different materials may be used.

The probe card 1′ in the present invention may include, for example, a bonding layer 3 so that the anodic oxide film wiring board 40 and the sintered ceramic wiring board 50 are bonded to each other.

When the sintered ceramic wiring board 50 is provided on the anodic oxide film wiring board 40 as shown in (a) of FIG. 7, a probe connection pad 6 is provided on the surface of the sintered ceramic wiring board 50, and a process of bonding the probe 16 may be performed according to the probe card manufacturing method. Herein, the side where the process of providing the probe 16 of the multilayer wiring board 2′ is directly performed may be configured with the sintered ceramic wiring board 50.

The sintered ceramic wiring board 50 is sintered by a high temperature sintering process, so that corrosion resistance to an etchant including an alkali solution may be excellent. Therefore, during the process of bonding the probe 16, a process of collectively providing the probes 16 may be efficiently performed without etching the surface of the multilayer wiring board 2′.

Such a structure makes it possible to perform the process of attaching the probes 16 collectively to the multilayer wiring board 2′ having a surface with strong corrosion resistance to the etchant, thereby rapidly producing products with high reliability.

When the sintered ceramic wiring board 50 is provided on the anodic oxide film wiring board 40, the multilayer wiring board 2′ may be composed of an anodic oxide film wiring board 40 except for the uppermost portion where the process of providing the probe 16 is directly performed.

In other words, in the multilayer wiring board 2′, the uppermost area where the probe 16 is directly provided is composed of a sintered ceramic wiring board 50, and the remaining area in which the pitch gap between terminals 8a of the circuit board 8 is compensated may be composed of the anodic oxide film wiring board 40. Such a structure may be advantageous in the process at a high temperature atmosphere, because most areas of the multilayer wiring board 2′ is made of a material of the anodic oxide film 30.

FIG. 6 is a view showing a state in which the probe card 1′ with the probe 16 is positioned above the electrode pad WP on the wafer W according to the probe card manufacturing method in the present invention. Accordingly, it may be a state where the tip of the probe 16 is inverted in such a manner as to face toward the electrode pad WP of the wafer W, after the process of bonding the probe 16 is performed.

In this way, the multilayer wiring board 2′ may be configured so that the surface on which the bonding process of the probe 16 is performed is made of a material (specifically, a sintered ceramic material) that has strong corrosion resistance to the etchant and the remaining area is made of a material of the anodic oxide film 30. Accordingly, the multilayer wiring board 2′ has an advantage of a material of the anodic oxide film 30 with less thermal deformation and an advantage of a sintered ceramic material with strong corrosion resistance to etchants containing alkaline solutions at the same time. As a result, by using the probe card manufacturing method according to the present invention, the probes 16 are collectively attached without damaging the multilayer wiring board 2′, thereby enabling rapid production of the probe card 1′.

Alternatively, the multilayer wiring board 2′ may include a sintered ceramic wiring board 50 under the anodic oxide film wiring board 40 as shown in (b) of FIG. 7. Herein, the anodic oxide film wiring board 40 may be provided so that the surface of the multilayer wiring board 2′ is composed of a barrier layer BL, and the sintered ceramic wiring board 50 may be provided below the anodic oxide film wiring board 40.

In such a structure, the side where the process of providing the probe 16 of the multilayer wiring board 2′ is directly performed may be composed of the anodic oxide film wiring board 40. Accordingly, the probe connection pad 6 may be provided on the surface of the barrier layer BL of the anodic oxide film wiring board 40.

When the sintered ceramic wiring board 50 is provided under the anodic oxide film wiring board 40, the sintered ceramic wiring board 50 having high rigidity may be configured to support the anodic oxide film wiring board 40. This makes it possible to be more effective in terms of securing the rigidity of the multilayer wiring board 2′.

Meanwhile, the multilayer wiring board 2′ is configured to include an anodic oxide film wiring board 40 made of a material f the anodic oxide film 30, and a resin insulating layer wiring board 60 provided on the top or bottom of the anodic oxide film wiring board 40 and composed of a resin insulating layer. Herein, the surface of the multilayer wiring board 2′ may be composed with a resin insulating layer.

The resin insulating layer may be composed of resin material, such as a liquid crystal polymer (for example, a polyester-based liquid crystal polymer), a thermoplastic resin such as a polyimide, a polyetherimide resin, or a polyamideimide resin, or a resin such as an epoxy resin, a polyamideimide resin, or a polyimide resin.

As an example, when the resin insulating layer is composed of a thermosetting resin and a plurality of resin insulating layers are laminated to produce the resin insulating layer wiring board 60, the resin insulating layer may be produced by molding an uncured product of a resin material into a predetermined layer shape, and then laminating and curing the same.

In contrast, when the resin insulating layer is composed of a thermoplastic resin, the resin insulating layer wiring board 60 may also be manufactured by laminating thermoplastic resin films and heating the same to be adhered to each other.

The resin insulating layer wiring board 60 may have a through hole penetrating in the thickness direction through laser processing using CO₂ laser or YAG laser on a part of the resin insulating layer and drilling processing such as reactive ion etching or solvent etching. Then, the through hole is filled with a conductor material to form a via conductor using a method such as sputtering, vapor deposition, plating, or filling a conductor paste, so that the via conductor may be formed inside. The via conductor may be the vertical wiring portion 4 of the multilayer wiring board 2.

The via conductor of the resin insulating layer wiring board 60 may be made of a metal material such as copper, silver, palladium, gold, platinum, aluminum, chromium, nickel, cobalt, titanium, tungsten, or a metal material alloy material thereof. Herein, the via conductor may be formed by filling the through hole with a metal paste prepared by mixing the above metal material powder with an organic solvent and a binder in, followed by heating to remove the organic component. As an example, a metal film forming technique such as a plating method or a sputtering method may be used in combination.

The resin insulating layer constituting the resin insulating layer wiring board 60 may be made of a resin material having a coefficient of thermal expansion equal to that of the aluminum oxide sintered body or the mullite sintered body, in order to minimize a difference in the thermal expansion coefficient between the resin insulating layer and the anodic oxide film wiring board 40.

Alternatively, the resin insulating layer wiring board may be made of a polyimide material. The polyimide material may have excellent properties in terms of insolubility, heat resistance, and chemical resistance. The polyimide wiring board 60 made of such a polyimide material may be manufactured separately from the anodic oxide film wiring board 40 so that they are bonded to each other by a bonding layer 3.

When the resin insulating layer wiring board 60 is provided on the anodic oxide film wiring board 40 as shown in (c) of FIG. 7, the probe connection pad 6 may be provided on only the surface of the resin insulating layer wiring board 60. Herein, the side where the process for bonding the probe 16 is performed may be composed of a material of the resin insulating layer. This makes it possible to implement a multilayer wiring board 2′ composed of the surface having corrosion resistance to the etchant.

As an example, in a structure in which the resin insulating layer wiring board 60 is provided on the top of the anodic oxide film wiring board 40, when the resin insulating layer wiring board 60 is made of polyimide material, and the temporary layer 11 of the base substrate 10 is made of, for example, Cu material, a copper etchant may be provided as an aqueous copper sulfate solution.

The aqueous copper sulfate solution is a solution that reacts with copper but does not react with polyimide. Therefore, in the process of separating the other end 16a′ of the probe 16 from the base substrate 10, one end 16c of the probe 16 being bonded to the probe connection pad 6, when removing the temporary layer 11 of Cu material, the polyimide wiring board 60 may not be damaged by the copper etchant.

Alternatively, a resin insulating layer wiring board 60 may be provided to the bottom of the anodic oxide film wiring board 40 as shown in (d) of FIG. 7. According to such a structure, in the resin insulating layer wiring board 60, it is easy to realize a narrow pitch of a wiring portion (e.g., a vertical wiring portion) provided therein.

When the multilayer wiring board 2′ is composed of the anodic oxide film wiring board 40 and the resin insulating layer wiring board 60, the entire area may be made of a material having heat resistance. Therefore, it is advantageous in a high temperature environment (such as a burn-in test).

In addition, when a resin insulating layer wiring board 60 is provided on the top of the anodic oxide film wiring board 40, the multilayer wiring board 2′ may be made of polyimide material with excellent chemical resistance. Accordingly, it is possible to prevent the problem that the surface is damaged due to the etchant during the bonding process of the probe 16.

In addition, when the resin insulating layer wiring board 60 is provided on the bottom of the anodic oxide film wiring board 40, since the anodic oxide film wiring board 40 is provided so that the barrier layer BL, which has high density and contains a large amount of aluminum to have relatively excellent chemical resistance, constitutes the surface of the multilayer wiring board 2′, it is possible to minimize the decrease in surface strength of the multilayer wiring board 2′.

Meanwhile, the multilayer wiring board 2′ is configured to include all of the anodic oxide film wiring board 40, the sintered ceramic substrate 50, and the resin insulating layer wiring board 60, which are provided in the probe cards 1 and 1′. Herein, the lamination structure of the anodic oxide film wiring substrate 40, the sintered ceramic substrate 50, and the resin insulating layer wiring board 60 may be achieved in various structures. When the multilayer wiring board 2′ is configured to include all of the anodic oxide film wiring board 40, the sintered ceramic substrate 50, and the resin insulating layer wiring board 60, since properties of the material constituting each wiring board 40, 50, and 60 may be used simultaneously, a more effective multilayer wiring board 2′ may be implemented. Specifically, in terms of the properties, in the case of anodic oxide film material, heat deformation is prevented, in the case of sintered ceramic material, high rigidity is obtained, and in the case of vertical material layer, it is easy to realize a narrow pitch.

As described above, although it has been described with reference to a preferred embodiment of the present invention, those skilled in the art can perform various modifications or variations of the present invention within the scope not departing from the spirit and scope of the present invention described in the following claims.

1. A method of manufacturing a probe card, the method comprising:
forming a temporary layer on a surface of a base substrate, forming a masking material layer on a surface of the temporary layer and patterning the masking material layer to form an open area, filling the open area with a conductive material, and removing the masking material layer excluding the conductive material by an etching process;
manufacturing a multilayer wiring board configured to have an anodic oxide film wiring board which is provided with a plurality of vertical wiring portions and horizontal wiring portions inside and made of an anodic oxide film material;
placing the base substrate, to which the conductive material is attached, above a probe connection pad of the multilayer wiring board to bond one end of the conductive material to the probe connection pad; and
removing the temporary layer of the base substrate through an etching process using an etchant to separate the other end of the conductive material from the base substrate.

2. The method of claim 1, wherein a surface of the multilayer wiring board is composed of a barrier layer.

3. The method of claim 1, wherein the manufacturing of the multilayer wiring board includes bonding a sintered ceramic wiring board to the top or bottom of the anodic oxide film wiring board.

4. The method of claim 1, wherein the manufacturing of the multilayer wiring board includes bonding a resin insulating layer wiring board composed of a resin insulating layer to the top or bottom of the anodic oxide film wiring board.

5. A probe card, comprising
a multilayer wiring board in which a vertical wiring portion and a horizontal wiring portion are provided and on which a probe connection pad is provided; and
a probe having one end connected to the probe connection pad,
wherein the multilayer wiring board is configured to include an anodic oxide film wiring board made of an anodic oxide film material, so that a surface of the multilayer wiring board is composed of a barrier layer, and the probe connection pad is provided on a surface of the barrier layer.

6. The probe card of claim 5, wherein the multilayer wiring board includes a sintered ceramic wiring board made of a sintered ceramic material provided on the bottom of the anodic oxide film wiring board.

7. The probe card of claim 5, wherein the multilayer wiring board includes a resin insulating layer wiring board composed of a resin insulating layer provided on the bottom of the anodic oxide film wiring board.

8. A probe card, comprising:
a multilayer wiring board in which a vertical wiring portion and a horizontal wiring portion are provided and on which a probe connection pad is provided; and
a probe connected to the probe connection pad,
wherein the multilayer wiring board includes an anodic oxide film wiring board made of an anodic oxide film material and a sintered ceramic wiring board made of a sintered ceramic material provided on the top of the anodic oxide film wiring board, and
the probe connection pad is provided on a surface of the sintered ceramic wiring board.

9. A probe card, comprising:
a multilayer wiring board in which a vertical wiring portion and a horizontal wiring portion are provided and on which a probe connection pad is provided; and
a probe connected to the probe connection pad,
wherein the multilayer wiring board is configured to include an anodic oxide film wiring board made of an anodic oxide film material and a resin insulating layer wiring board made of a resin insulating layer provided on the top of the anodic oxide film wiring board, and the probe connection pad is provided on a surface of the resin insulating layer wiring board.
